(19) United States
(12) Patent Application Publication
(10) Pub. No.: US 2007/0254092 A1
(43) Pub. Date: Nov. 1, 2007

(54) Systems and Methods for Detecting Abnormal Dispense of Semiconductor Process Fluids

(75) Inventors: Y. Sean LIN, IRVINE, CA (US); Tetsuya Ishikawa, SARATOGA, CA (US)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: APPLIED MATERIALS, INC., SANTA CLARA, CA (US)

(21) Appl. No.: 11/380,912

(22) Filed: Apr. 28, 2006

(51) Int. Cl. C23C 16/52; B05C 11/00

(52) U.S. Cl. 427/8; 118/712; 118/663; 118/667; 118/692

(57) ABSTRACT

Systems and methods for monitoring a dispense of a semiconductor process liquid are provided. A motor is driven to dispense the semiconductor process liquid in accordance with a liquid delivery plan. The delivery plan corresponds to a reference profile. A signal profile from a sensor is measured while the motor dispenses the process liquid in accordance with the plan. The measured profile is compared with a reference profile to characterize the dispense.

### BACKGROUND OF THE INVENTION

The present invention relates generally to the field of substrate processing equipment. More particularly, the present invention relates to a method and apparatus for providing delivery, monitoring and detection of dispense errors, of with fluids used for semiconductor process chemistry. Merely by way of example, the method and apparatus of the present invention are used to deliver, dispense and detect liquids, for example photoresist dispensed from a pump with a electric motor, dispensed in a photolithography coating system. The method and apparatus can be applied to other processes for semiconductor substrates, for example those used in the formation of integrated circuits.

Modern integrated circuits contain millions of individual elements that are formed by patterning the materials, such as silicon, metal and/or dielectric layers, that make up the integrated circuit to sizes that are small fractions of a micrometer. The technique used throughout the industry for forming such patterns is photolithography. A typical photolithography process sequence generally includes depositing one or more uniform photoresist (resist) layers on the surface of a substrate, drying and curing the deposited layers, patterning the substrate by exposing the photoresist layer to electromagnetic radiation that is suitable for modifying the exposed layer and then developing the patterned photoresist layer.

It is common in the semiconductor industry for many of the steps associated with the photolithography process to be performed in a multi-chamber processing system (e.g., a cluster tool) that has the capability to sequentially process semiconductor wafers in a controlled manner. One example of a cluster tool that is used to deposit (i.e., coat) and develop a photoresist material is commonly referred to as a track lithography tool.

Track lithography tools typically include a mainframe that houses multiple chambers (which are sometimes referred to herein as stations) dedicated to performing the various tasks associated with pre- and post-lithography processing. There are typically both wet and dry processing chambers within track lithography tools. Wet chambers include coat and/or develop bowls, while dry chambers include thermal control units that house bake and/or chill plates. Track lithography tools also frequently include one or more pod/cassette mounting devices, such as an industry standard FOUP (front opening unified pod), to receive substrates from and return substrates to the clean room, multiple substrate transfer robots to transfer substrates between the various chambers/stations of the track tool and an interface that allows the tool to be operatively coupled to a lithography exposure tool in order to transfer substrates into the exposure tool and receive substrates from the exposure tool after the substrates are processed within the exposure tool.

Over the years there has been a strong push within the semiconductor industry to shrink the size of semiconductor devices. The reduced feature sizes have caused the industry's tolerance to process variability to shrink, which in turn, has resulted in semiconductor manufacturing specifications having more stringent requirements for process uniformity and repeatability. An important factor in minimizing process variability during track lithography processing sequences is to ensure that every substrate processed within the track lithography tool for a particular application has the same “wafer history.” A substrate's wafer history is generally monitored and controlled by process engineers to ensure that all of the device fabrication processing variables that may later affect a device's performance are controlled, so that all substrates in the same batch are always processed the same way.

A component of the “wafer history” is the thickness, uniformity, repeatability, and other characteristics of the photolithography chemistry, which includes, without limitation, photoresist, developer, and solvents. Generally, during photolithography processes, a substrate, for example a semiconductor wafer, is rotated on a spin chuck at predetermined speeds while liquids and gases such as solvents, photoresist (resist), developer, and the like are dispensed onto the surface of the substrate. Typically, the wafer history will depend on the process parameters associated with the photolithography process.

As an example, an inadequate volume of photoresist dispensed during a coating operation will generally impact the uniformity and thickness of coatings formed on the substrate. Additionally, the dispense rate of the photoresist will generally impact film properties, including the lateral spreading of the resist in the plane of the substrate. In some instances, therefore, it is desirable to control both the volume and dispense rate of the photoresist applied to the substrate with respect to both the accuracy (e.g., total volume per dispense event) and repeatability (e.g., difference in volume per dispense over a series of dispense events) of the dispense process.

Work in relation to the present invention suggests that known methods of monitoring and dispensing liquids may be less than ideal. For example, known pumps which use encoder feedback to make sure a motor is at the right position may not detect the actual load on the motor, and therefore may not detect under delivery due to bubbles or under fill. Also, known systems and methods for fluid delivery that use an optical sensor to control dispense to an end-point based on spread of a liquid chemical to a certain position on the wafer can fail to detect subtle changes in dispense characteristics and can have limited accuracy with respect to an amount of liquid dispensed. Known systems which use pressure sensors to signal needed filter changes and provide an alarm when pumping fails may not detect subtle changes in dispense characteristics that can affect yields. As it could be beneficial to provide real time detection of subtle changes in dispense characteristics which affect yields and efficiency, further improvements are desired and are continuously sought by process engineers. Therefore, there is a need in the art for improved methods and apparatus for controlling the dispensed liquids in a photolithography system.

### SUMMARY OF THE INVENTION

According to the present invention, techniques related to the field of semiconductor processing equipment are provided. More particularly, the present invention includes a method and apparatus for providing delivery, monitoring and detection of dispense errors, with fluids used for semiconductor process chemistry. Merely by way of example, the method and apparatus of the present invention have been applied to delivery, dispense and detection liquids, for example photoresist dispensed from a pump with an electric motor, dispensed in a photolithography coating system. The method and apparatus can be applied to other processes for semiconductor substrates, for example those used in the formation of integrated circuits.

In an embodiment of the present invention, a method of monitoring a dispense of a semiconductor process liquid is provided. The method includes driving a motor to dispense the semiconductor process liquid in accordance with a liquid delivery plan. The delivery plan corresponds to a reference profile. A signal profile from a sensor is measured while the motor dispenses the process liquid in accordance with the plan. The measured profile is compared with a reference profile to characterize the dispense. The reference profile corresponds to the delivery plan.

In some embodiments of the present invention a device for monitoring a dispense of a semiconductor process liquid is provided. An electrical motor is adapted to dispense a semiconductor process liquid in accordance with a liquid delivery plan. A sensor is adapted to measure a profile of a dispense characteristic while the motor dispenses the liquid. A processor is coupled to the sensor. The processor is adapted to determine a reference profile to correspond with the delivery plan, the processor adapted to compare the measured profile with the reference profile to characterize the dispense. In specific embodiments, the sensor comprises at least one of a current sensor, a pressure sensor, a temperature sensor, or an optical sensor.

Many benefits are achieved by way of the present invention over conventional techniques. For example, an embodiment provides a device for monitoring a dispense of a semiconductor process liquid in which a motor dispenses the semiconductor process liquid in accordance with a liquid delivery plan, and a measured signal profile is compared to a reference signal profile to characterize the dispense. This comparison of a measured signal profile to a reference signal profile can detect subtle variations in the dispense, for example variations that cause minor changes in the amount of liquid dispensed, and provide a warning to an operator prior to system failure. A particular embodiment provides a current sensor to measure a current profile, so that subtle variations in the delivery of the liquid can be readily detected based on deviations in the measured current profile from the reference profile. Depending upon the embodiment, one or more of these benefits, as well as other benefits, may be achieved. These and other benefits will be described in more detail throughout the present specification and more particularly below in conjunction with the following drawings.

### BRIEF DESCRIPTION OF THE DRAWINGS

FIG. 1 is a simplified plan view of an embodiment of a track lithography tool according to an embodiment of the present invention;

FIG. 2 is a simplified schematic illustration of a photolithography chemical dispense apparatus according to an embodiment of the present invention;

FIG. 3A is a simplified schematic illustration of a device to monitor dispense of a semiconductor process liquid with a motor and a current sensor according to an embodiment of the present invention;

FIG. 3B is a simplified schematic illustration of device to monitor dispense of a semiconductor process liquid with a pressure sensor according to an embodiment of the present invention;

FIG. 3C is a simplified schematic illustration of a device to monitor dispense of a semiconductor process liquid with a temperature sensor according to an embodiment of the present invention;

FIG. 3D is a simplified schematic illustration of a device to monitor dispense of a semiconductor process liquid with an optical sensor according to an embodiment of the present invention;

FIG. 3E is a simplified schematic illustration of a device using a combination of sensors as in FIGS. 3A to 3D according to an embodiment of the present invention;

FIG. 3F is a simplified illustration of a sensor profile according to an embodiment of the present invention; and

FIG. 4 is a flow chart which illustrates a method of monitoring a dispense of a semiconductor process liquid according to an embodiment of the present invention.

### DESCRIPTION OF SPECIFIC EMBODIMENTS

According to the present invention, techniques related to the field of semiconductor processing equipment are provided. More particularly, the present invention includes a method and apparatus for providing delivery, monitoring and detection of dispense errors, of fluids used for semiconductor process chemistry. Merely by way of example, the method and apparatus of the present invention have been applied to delivery, dispense and detection liquids, for example photoresist dispensed from a pump with an electric motor, dispensed in a photolithography coating system. The method and apparatus can be applied to other processes for semiconductor substrates, for example those used in the formation of integrated circuits.

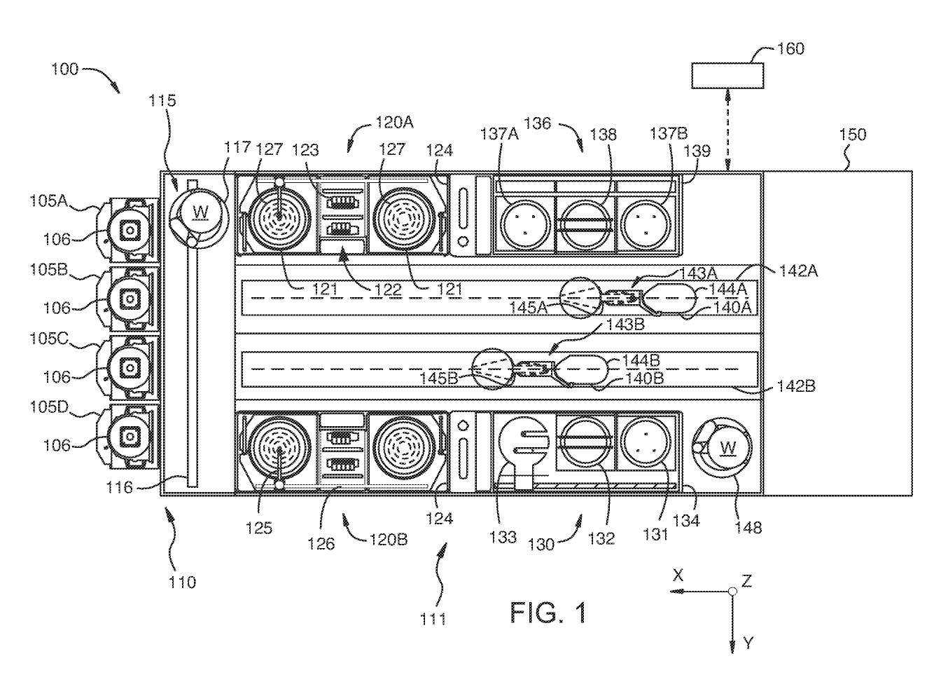

FIG. 1 is a plan view of an embodiment of a track lithography tool 100 in which the embodiments of the present invention may be used. As illustrated in FIG. 1, track lithography tool 100 contains a front end module 110 (sometimes referred to as a factory interface or FI) and a process module 111. In other embodiments, the track lithography tool 100 includes a rear module (not shown), which is sometimes referred to as a scanner interface. Front end module 110 generally contains one or more pod assemblies or FOUPS (e.g., items 105A-D) and a front end robot assembly 115 including a horizontal motion assembly 116 and a front end robot 117. The front end module 110 may also include front end processing racks (not shown). The one or more pod assemblies 105A-D are generally adapted to accept one or more cassettes 106 that may contain one or more substrates or wafers, “W,” that are to be processed in track lithography tool 100. The front end module 110 may also contain one or more pass-through positions (not shown) to link the front end module 110 and the process module 111.

Process module 111 generally contains a number of processing racks 120A, 120B, 130, and 136. As illustrated in FIG. 1, processing racks 120A and 120B each include a coater/developer module with shared dispense 124. A coater/developer module with shared dispense 124 includes two coat bowls 121 positioned on opposing sides of a shared dispense bank 122, which contains a number of nozzles 123 providing processing fluids (e.g., bottom anti-reflection coating (BARC) liquid, resist, developer, and the like) to a wafer mounted on a substrate support 127 located in the coat bowl 121. In the embodiment illustrated in FIG. 1, a dispense arm 125 sliding along a track 126 is able to pick up a nozzle 123 from the shared dispense bank 122 and position the selected nozzle over the wafer for dispense operations. Of course, coat bowls with dedicated dispense banks are provided in alternative embodiments.

Processing rack 130 includes an integrated thermal unit 134 including a bake plate 131, a chill plate 132, and a shuttle 133. The bake plate 131 and the chill plate 132 are utilized in heat treatment operations including post exposure bake (PEB), post-resist bake, and the like. In some embodiments, the shuttle 133, which moves wafers in the x-direction between the bake plate 131 and the chill plate 132, is chilled to provide for initial cooling of a wafer after removal from the bake plate 131 and prior to placement on the chill plate 132. Moreover, in other embodiments, the shuttle 133 is adapted to move in the z-direction, enabling the use of bake and chill plates at different z-heights. Processing rack 136 includes an integrated bake and chill unit 139, with two bake plates 137A and 137B served by a single chill plate 138.

One or more robot assemblies (robots) 140 are adapted to access the front-end module 110, the various processing modules or chambers retained in the processing racks 120A, 120B, 130, and 136, and the scanner 150. By transferring substrates between these various components, a desired processing sequence can be performed on the substrates. The two robots 140 illustrated in FIG. 1 are configured in a parallel processing configuration and travel in the x-direction along horizontal motion assembly 142. Utilizing a mast structure (not shown), the robots 140 are also adapted to move in a vertical (z-direction) and horizontal directions, i.e., transfer direction (x-direction) and a direction orthogonal to the transfer direction (y-direction). Utilizing one or more of these three directional motion capabilities, robots 140 are able to place wafers in and transfer wafers between the various processing chambers retained in the processing racks that are aligned along the transfer direction.

Referring to FIG. 1, the first robot assembly 140A and the second robot assembly 140B are adapted to transfer substrates to the various processing chambers contained in the processing racks 120A, 120B, 130, and 136. In one embodiment, to perform the process of transferring substrates in the track lithography tool 100, robot assembly 140A and robot assembly 140B are similarly configured and include at least one horizontal motion assembly 142, a vertical motion assembly 144, and a robot hardware assembly 143 supporting a robot blade 145. robot assemblies 140 are in communication with a system controller 160. In the embodiment illustrated in FIG. 1, a rear robot assembly 148 is also provided.

The scanner 150, which may be purchased from Canon USA, Inc. of San Jose, Calif., Nikon Precision Inc. of Belmont, Calif., or ASML US, Inc. of Tempe Arizona, is a lithographic projection apparatus used, for example, in the manufacture of integrated circuits (ICs). The scanner 150 exposes a photosensitive material (resist), deposited on the substrate in the cluster tool, to some form of electromagnetic radiation to generate a circuit pattern corresponding to an individual layer of the integrated circuit (IC) device to be formed on the substrate surface.

Each of the processing racks 120A, 120B, 130, and 136 contain multiple processing modules in a vertically stacked arrangement. That is, each of the processing racks may contain multiple stacked coater/developer modules with shared dispense 124, multiple stacked integrated thermal units 134, multiple stacked integrated bake and chill units 139, or other modules that are adapted to perform the various processing steps required of a track photolithography tool. As examples, coater/developer modules with shared dispense 124 may be used to deposit a bottom antireflective coating (BARC) and/or deposit and/or develop photoresist layers. Integrated thermal units 134 and integrated bake and chill units 139 may perform bake and chill operations associated with hardening BARC and/or photoresist layers after application or exposure.

In one embodiment, a system controller 160 is used to control all of the components and processes performed in the cluster tool 100. The controller 160 is generally adapted to communicate with the scanner 150, monitor and control aspects of the processes performed in the cluster tool 100, and is adapted to control all aspects of the complete substrate processing sequence. The controller 160, which is typically a microprocessor-based controller, is configured to receive inputs from a user and/or various sensors in one of the processing chambers and appropriately control the processing chamber components in accordance with the various inputs and software instructions retained in the controller's memory. The controller 160 generally contains memory and a CPU (not shown) which are utilized by the controller to retain various programs, process the programs, and execute the programs when necessary. The memory (not shown) is connected to the CPU, and may be one or more of a readily available memory, such as random access memory (RAM), read only memory (ROM), floppy disk, hard disk, or any other form of digital storage, local or remote. Software instructions and data can be coded and stored within the memory for instructing the CPU. The support circuits (not shown) are also connected to the CPU for supporting the processor in a conventional manner. The support circuits may include cache, power supplies, clock circuits, input/output circuitry, subsystems, and the like all well known in the art. A program (or computer instructions) readable by the controller 160 determines which tasks are performable in the processing chamber(s). Preferably, the program is software readable by the controller 160 and includes instructions to monitor and control the process based on defined rules and input data.

It is to be understood that embodiments of the invention are not limited to use with a track lithography tool such as that depicted in FIG. 1. Instead, embodiments of the invention may be used in any track lithography tool including the many different tool configurations described in U.S. application Ser. No. 11/112,281, entitled “Cluster Tool Architecture for Processing a Substrate” filed on Apr. 22, 2005, which is hereby incorporated by reference for all purposes and including configurations not described in the above referenced application.

Generally, track lithography tools are used to dispense precise amounts of expensive lithography chemicals onto substrates to form thin, uniform coatings. For modern lithography processes, the volumes of chemicals, such as photoresist, dispensed per event are small, for example, ranging from about 0.5 ml to about 5.0 ml. The volume of chemical dispensed, and the flow rate during the dispense operation, among other variables, are controlled during the process of dispensing the lithography chemicals, for example, photoresist. Preferably, control of the dispense operations in a track lithography tool provide actual dispensed volumes with an accuracy of ±0.02 milliliters (ml) and repeatability from dispense event to dispense event of 3σ<0.02 ml.

A wide variety of photolithography chemicals are utilized in track lithography tools according to embodiments of the present invention. For example, photoresist, bottom anti-reflective coating (BARC), top anti-reflective coating (TARC), top coat (TC), Safier, and the like are dispensed onto the substrate. In some embodiments, after the selected chemical is dispensed, the substrate is spun to create a uniform thin coat on an upper surface of the substrate. Generally, to provide the levels of uniformity desired of many photolithography processes, dispense events start with a solid column of chemical. The flow rate is generally set at a predetermined rate as appropriate to a particular chemical deliver process. For example, the flow rate of the fluids is selected to be greater than a first rate in order to prevent the fluids from drying out prior to dispense. At the same time, the flow rate is selected to be less than a second rate in order to maintain the impact of the fluid striking the substrate below a threshold value.

As the dispense event is terminated, the fluid is typically drawn back into the dispense line, sometimes referred to as a suck-back process utilizing a suck-back valve. In some track lithography tools, the fluid is brought back into the dispense line about 1-2 mm from the end of the dispense nozzle, forming a reverse meniscus. This suck-back process prevents the lithography chemicals from dripping onto the substrate and prevents the chemicals from drying out inside the nozzle.

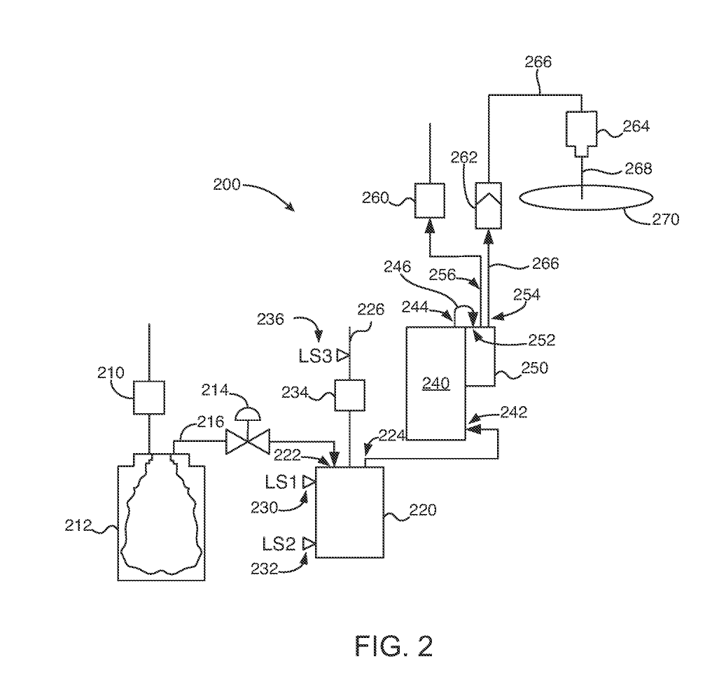

FIG. 2 is a simplified schematic illustration of a photolithography chemical dispense apparatus 200 according to an embodiment of the present invention. A pressure valve 210 is coupled to a source bottle 212 containing the photolithography chemical to be dispensed onto the substrate surface. In an embodiment, the source bottle is a NOWPak® container available from ATMI, Inc., Danbury, Conn. The source bottle is coupled to a flow control valve 214 and adapted to regulate the flow of the photolithography chemical in fluid line 216. Buffer vessel 220 is illustrated in FIG. 2 and includes an input port 222, an output port 224, and a vent port 226. The input port 222 of the buffer vessel 220 is coupled to the fluid line 216. As illustrated in FIG. 2, the buffer vessel includes a number of level sensors, for example, level sensor LS1 (230) and level sensor LS2 (232). As described more fully below, the level sensors are utilized to regulate the volume of photolithography chemical present in the buffer vessel 220.

The vent port 226 of the buffer vessel is coupled to a vent valve 234 and a level sensor LS3 (236). Level sensor LS3 serves to monitor the level of fluid passing through the vent valve 234. The output port 224 of the buffer vessel is coupled to input port 242 of dispense pump 240. As illustrated in FIG. 2, a filter 250 is integrated with the dispense pump 240 and the output port 244 of the dispense pump is coupled to an input port 252 of the filter 250. A line 246 couples output port 244 of the dispense pump 240 to input port 252 of the filter vent port 256 and an output port 254 are provided on the filter 250 and, as illustrated in FIG. 2, a vent valve 260 is coupled to the filter vent port 256. A valve 262 is coupled to the fluid line running from the output port 254 of the filter. Valve 262 includes a flow valve and a suck back valve and is often referred to as a suck back valve. A fluid line 266 couples valve 262 with a nozzle 264. Nozzle 264 dispenses the semiconductor process liquid. From valve 262, the photolithography chemical is delivered to substrate 270 through nozzle 264. The photolithography chemical forms a stream 268 as the liquid exits nozzle 264. As will be evident to one of skill in the art, apparatus adapted to chuck and spin the substrate are not illustrated for purposes of clarity.

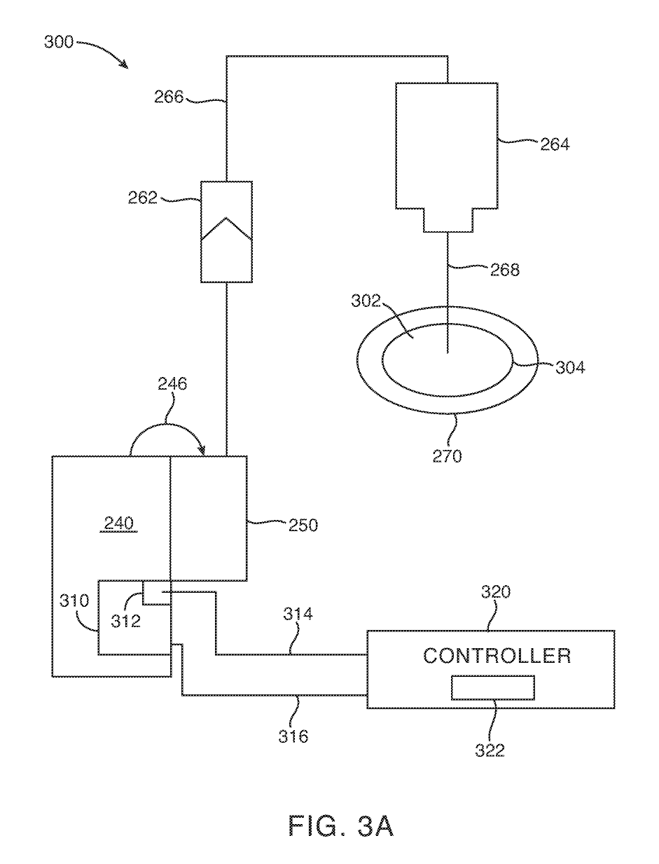

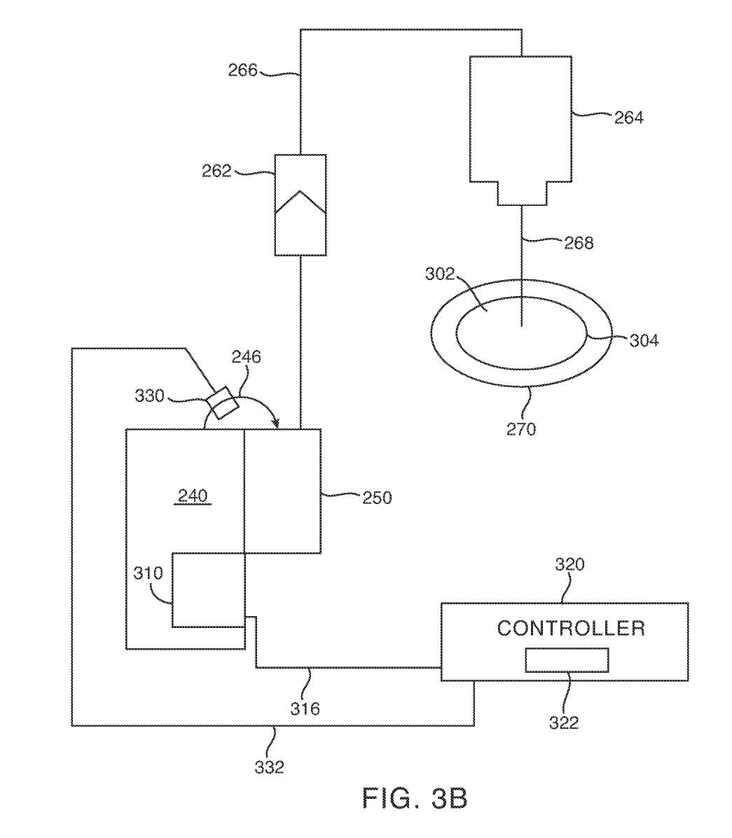

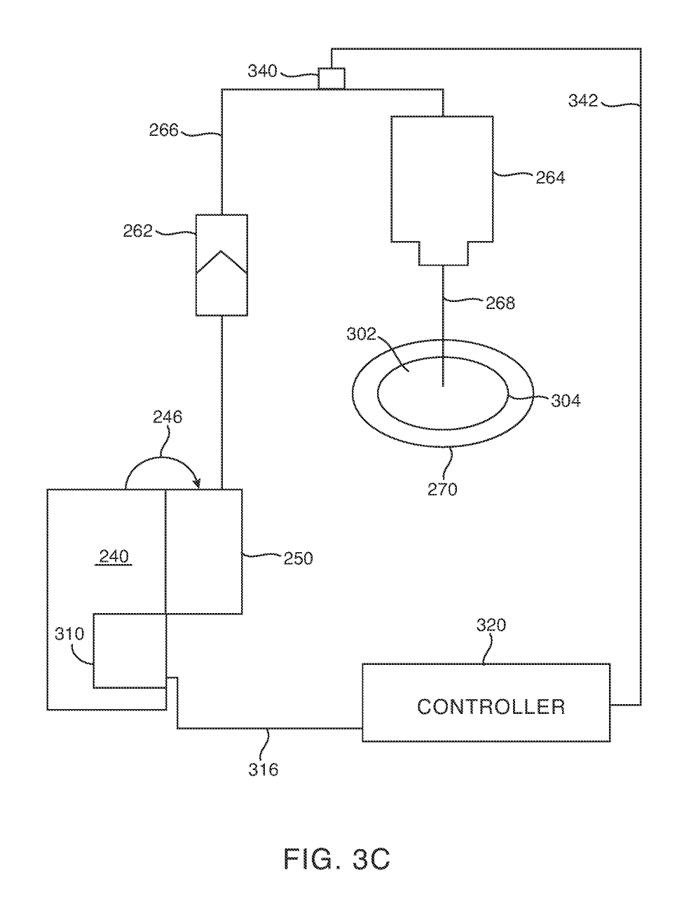

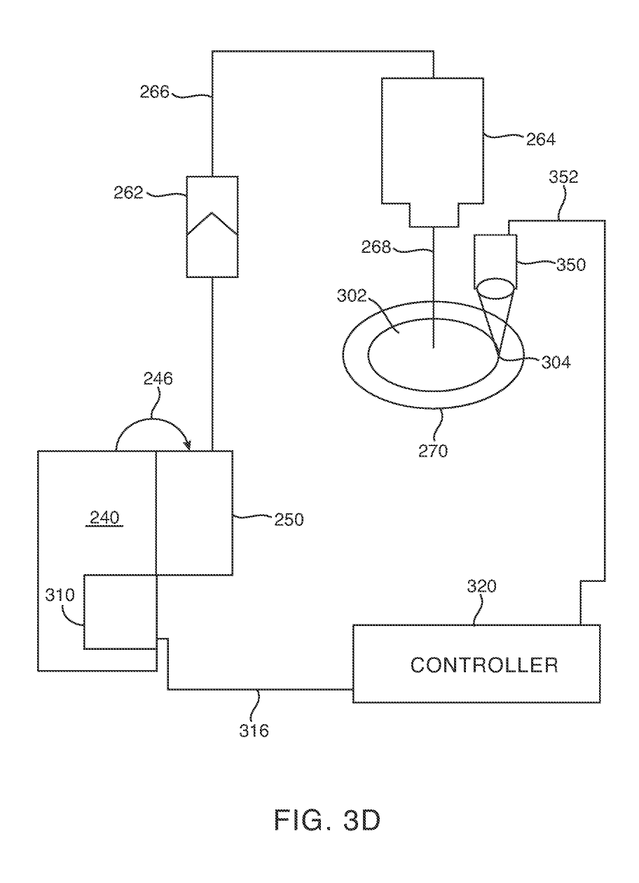

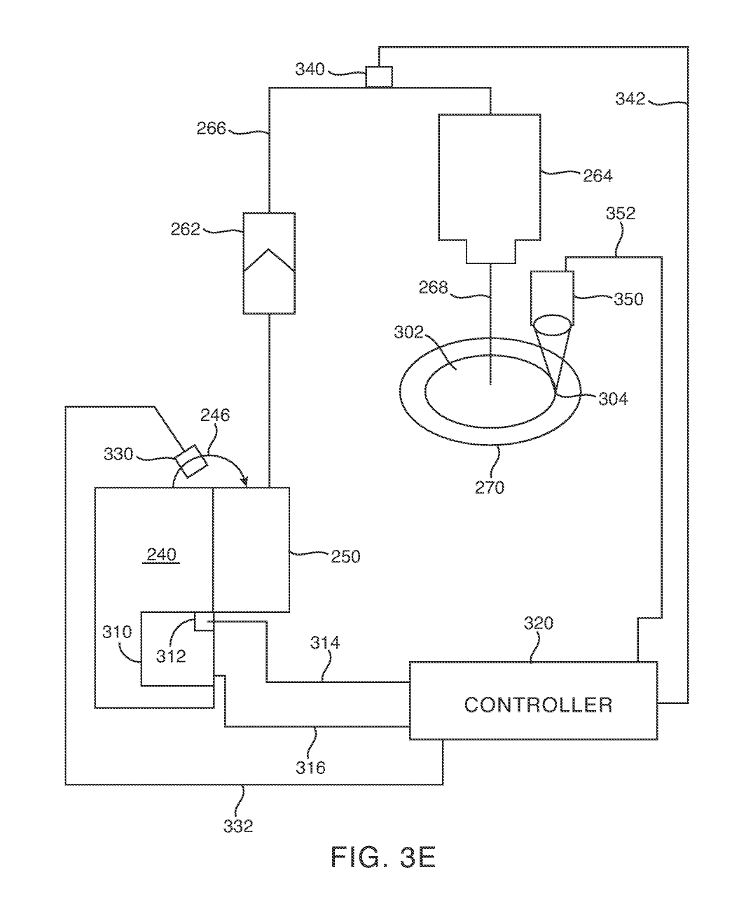

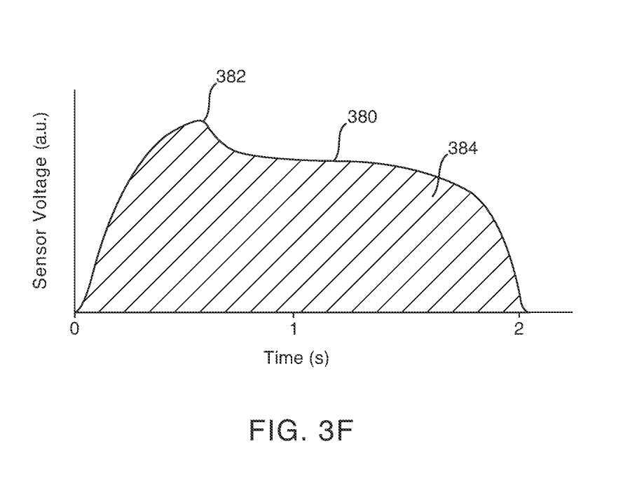

FIG. 3A is a simplified schematic illustration of a device 300 to monitor dispense of a semiconductor process liquid with a motor 310 and a current sensor 312 according to an embodiment of the present invention. Nozzle 264 applies stream 268 of a semiconductor process liquid 302 to substrate 270. As liquid 302 is deposited on substrate 270, the liquid spreads to a location 304 on the substrate. As the substrate usually spins, the liquid spreads in a rotationally pattern, for example a disc. Dispense pump 240 includes a motor 310. Current sensor 312 measures current applied to motor 310 while the motor dispenses the liquid. A line 316 couples a controller 320 to motor 310. Controller 320 includes a tangible medium 322. Controller 320 controls motor 310 with signals sent over line 316 from controller 320 to motor 310. Controller 320 controls a dispense of the liquid with motor 310 so that the liquid is delivered according to a liquid delivery plan, for example 1 milliliter (ml) in 1 second (s). A line 314 couples current sensor 314 to controller 320. Current sensor 314 measures current to motor 310 while the motor dispenses the liquid. This current to the motor is a characteristic of the dispense which is related physical characteristics of the device, for example the viscosity of the liquid, the impurities captured by the filter, any air present in the line, restriction of nozzle 264, and the like. Controller 320 generates a current profile from current sensor 312. Tangible 322 medium stores reference profiles which are compared to the measured current profile.

Several pumps have motors which can be used in accordance with embodiments of the present invention. For example, Entegris of Chaska, Minn., manufactures a pump suitable for incorporation as dispense pump 240. An Entegris IntelliGen-Mini pump includes a servo motor. Current to the servo motor can be measured with a current sensor as described above. The current sensor can be built into the pump, or include an external circuit built to monitor current to the pump. Any photoresist pump which uses a servo motor to deliver liquid can be incorporated as dispense pump 240, and the current to the servo motor is measured while the motor drives the pump to deliver the liquid.

While the controller can be any device which modifies an electrical signal, for example a phase comparator, a programmable array logic device or a microcontroller, the controller often comprises at least one microprocessor and at least one tangible medium for storing instructions for the controller. The tangible medium comprises random access memory (RAM) and can comprise read only memory (ROM), compact disk ROM (CDROM), flash RAM or the like. Controller 320 can comprise a distributed network of computers, for example a local area network, an intranet or Internet. Controller 320 communicates with processor 160, described above, and in some embodiments processor 160 comprises controller 320. Machine readable instructions for performing at least some of the techniques described herein are stored on the tangible medium.

Controller 320 compares a measured profile from a measured signal, for example a current profile from the measured current signal, to a reference profile to characterize the dispense. The current profile includes an integral of the current to the motor while the motor dispenses the liquid according to the liquid delivery plan. The current profile includes a peak current to the motor while the motor dispenses the liquid according to the liquid delivery plan. In some embodiments, the current profile is generated with an circuit, for example an analog circuit which integrates the current applied to the motor and detects a peak current to the motor while the pump dispenses the liquid. The current profile can also be integrated while the motor dispenses the liquid. The current profile can be measured with an integration circuit, for example an analog integration circuit. The analog circuits are included with current sensor 312 and can be included with controller 320. In some embodiments, the current profile includes several measurement of current over time while the motor dispenses the liquid according to the liquid delivery plan, for example a plot of current over time. In such embodiments a peak detection algorithm of the controller can detect the peak and an integration algorithm can calculate the area under the plot to determine the integral of the current to the motor over the dispense time.

The controller determines a reference profile to compare with the measured profile, for example the current profile, so that the reference profile corresponds to the measured profile. Several reference profiles are stored on tangible medium 322. The reference profiles include a typical profile, for example a profile obtained immediately after the apparatus has been calibrated so that any variation from the reference profile indicates a change in the status of the apparatus. Each liquid delivery plan corresponds to an amount of liquid delivered over a period of time, for example 2 ml in 0.5 s. The profiles for several liquid delivery plans are obtained, for example delivery plans of 2 ml in 0.5 s, 2 ml in 2 s, 0.5 ml in 0.5 s, 0.5 ml in 2 s, and the like. Each delivery plan can also correspond to a liquid delivered to the substrate, for example photoresist, bottom anti-reflective coating (BARC), top anti-reflective coating (TARC), top coat (TC), Safier, and the like If the liquid delivery plan exactly matches a delivery plan for a reference profile stored on the tangible medium, the processor selects the stored reference profile matching the liquid delivery plan to determine the reference profile. If the liquid delivery plan does not exactly match the liquid delivery plan of one of the reference profiles, the controller will calculate the reference profile to determine the reference profile, for example by interpolation.

FIG. 3B is a simplified schematic illustration of device to monitor dispense of a semiconductor process liquid with a pressure sensor 330 according to an embodiment of the present invention. Pressure sensor 330 is connected to controller 320 with a line 332. Controller 320 measures current from current sensor 330 while the pump delivers the liquid according to the liquid delivery plan as described above. Controller 320 generates a pressure profile. The pressure profile includes and integral and a peak pressure while the motor delivers the liquid according to the liquid delivery plan. An analog circuit connected to the pressure sensor detects the peak pressure and integrates the pressure signal. The analog circuit includes a reset so that the controller can reset the circuit before each dispense. In some embodiments, controller 320 can includes a circuit to measure the peak pressure and the integral of the pressure over time while the pump delivers the liquid. The profile can include pressure over time data while the motor dispenses the liquid, for example as a plot of pressure over time.

Several pumps and pressure sensor locations are suitable for incorporation of pressure sensors according to embodiments of the present invention. As shown in FIG. 3B, pressure sensor 330 is placed along line 246 to detect pressure between dispense pump 240 and filter 250. This location allows detection of filter clogging and suck back valve failure when pressure is high, and also allows detection of more subtle changes in pressure due to partial blockage of filter 250 or valve 262. The pressure sensor can also be placed between valve 262 and filter 250 and between nozzle 264 and valve 262. Examples of pumps which can be used include IntelliGen pumps as described above and IDI pumps of Carrollton, Tex., for example model BP-5X. Commercially available versions of IntlliGen and IDI pumps monitor pressure, and such pumps can be used and/or modified to provide a measured pressure profile while liquid is delivered with a liquid delivery plan, in accordance with embodiments of the present invention. In embodiments that use a secondary fluid to drive the pump, the sensor can be positioned to measure the pressure of the secondary fluid, for example with an Twaki PDS pump available from Twaki America Inc. of Holliston, Mass., and a CT6 pump available from Koganei of Tokyo, Japan.

FIG. 3C is a simplified schematic illustration of a device to monitor dispense of a semiconductor process liquid with a temperature sensor 340 according to an embodiment of the present invention. Temperature sensor 340 is connected to controller 320 with a line 342. Temperature of the photo resist is tightly controlled, typically to within +/−0.1° C. Thus, detection of fluctuations in temperature is desirable. A water jacket surrounds fluid line 266 and has a water inlet and a water outlet. Temperature sensor 340 can be positioned at several places near fluid line 266. As shown in FIG. 3C, temperature sensor 340 is positioned to measure the temperature of the photo resist in fluid line 266 as the liquid is delivered, for example inside the water jacket near the inlet of the water jacket. Thus, temperature sensor 340 is connected to a tubing wall of fluid line 266 to measure temperature fluctuations as liquid is delivered. Temperature sensor 340 can detect fluctuations in temperature as the liquid is delivered, for example temperature spikes and peaks. Temperature sensor 340 can also be embedded in the tubing wall. Fluid line 266 is surrounded by a water jacket (not shown). The temperatures sensor can be positioned at the outlet of the water jacket. Several temperature sensors can be used to measure the temperature, for example resistance temperature detectors (RTD), thermocouples, thermistors, and the like. Suitable sensors are available from Watlow of St. Louis, Mo. and Omron Electronics of Schaumburg, Ill.

FIG. 3D is a simplified schematic illustration of a device to monitor dispense of a semiconductor process liquid with an optical sensor 350 according to an embodiment of the present invention. Optical sensor 350 is connected to controller 320 with a line 352. Optical sensor is a charge coupled device (CCD) camera, and can be any device which measures a change in optical characteristics at the surface of substrate 270, for example changes in reflectivity as liquid 302 is deposited on substrate 270. For example optical sensor 350 can comprise a CMOS sensor, a linear array sensor, a position sensing detector, a photo diode, a photo transistor and the like. Optical sensor 350 and controller 320 measure a period of time for semiconductor process liquid 302 to reach location 304 after dispense pump 240 dispenses the liquid and the wafer starts to spin at a high rate. In some embodiments, optical sensor 350 and controller 320 measure a period of time for liquid 320 to a reach location on the substrate while dispense pump 240 dispense the liquid. This period of time is compared to a reference time period which corresponds to the delivery plan. Optical sensor 350 can also measure the position of the edge of the liquid as the liquid moves outward on substrate 270 while dispense pump 240 dispenses the liquid. Thus, optical sensor 350 can provide position versus time data for the liquid 302 while the pump dispenses the liquid. A derivative of this data can be taken to provide velocity versus time data. The position versus time data can also be integrated. The optical sensor profile can include the period of time for the liquid to spread to the location, the position versus time data, the velocity versus time data, and/or an integral of the position versus time data.

FIG. 3E is a simplified schematic illustration of a device using a combination of sensors as in FIGS. 3A to 3D according to an embodiment of the present invention. It will be recognized that the embodiments of FIGS. 3A to 3D can be combined in any way number of ways. Any combination of the above sensors can be made. For example, a pressure sensor can be combined with a current sensor to provide simultaneous pressure profiles and current profiles while the liquid is dispensed according to the liquid delivery plan. Also, an optical sensor can be combined with a current sensor to provide simultaneous optical sensor profiles and current profiles while the liquid is dispensed according to the liquid delivery plan. As illustrated in FIG. 3E, all of the sensors can be combined and can simultaneously generate sensor profile data while the pump delivers liquid according to a liquid delivery plan.

FIG. 3F is a simplified illustration of a sensor profile 380 according to an embodiment of the present invention. Sensor profile 380 comprises a plot of current from current sensor 312 versus time, and the sensor profile can comprise any sensor signal including voltage and digital signals. Any of the above sensors can be used to generate sensor profiles similar to sensor profile 380, and any of these sensor profiles can be compared to reference profiles as described above. Sensor profile 380 includes a peak 382 that can be detected as described above. Sensor profile 380 includes an area 384 under the curve. Area 384 can be measured by integration as described above. In an embodiment, the sensor profile is used to generate a reference profile as described above, for example when the sensor profile is obtained immediately after the system has been calibrated and the profile is stored on the tangible medium as a reference profile.

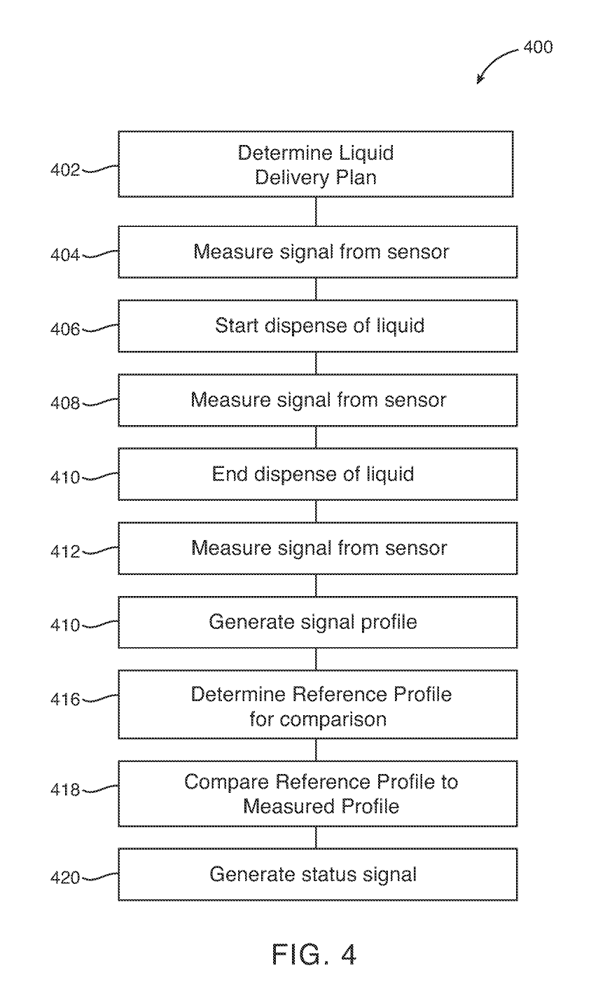

FIG. 4 is a flow chart which illustrates a method 400 of monitoring a dispense of a semiconductor process liquid according to an embodiment of the present invention. A step 402 determines a liquid delivery plan. For example the operator selects a delivery plan from a menu. The operator can enter the value into the controller by typing in values. The delivery plan includes a volume of liquid delivered over a period of time, for example 0.5 ml in 2 s. A step 404 measures a signal from the sensor, for example a pressure sensor. The measured signal can be any signal or combination of signals as described above. With step 404 the signal from the sensor is measured before the dispense operation to obtain a baseline sensor measurement corresponding to the condition of the dispense apparatus prior to the dispense operation. Step 406 starts the dispense of the liquid. A command from the controller starts the dispense as described above. A step 408 measures a signal from the sensor. The signal from the sensor is measured throughout the dispense process, although the measured sensor data can be an array of discrete values corresponding to sensor signal measurements over a period of time. A step 410 ends the dispense of the liquid. A command from the controller closes the flow valve as described above. A step 412 measures a signal from the sensor. The signal is measured after the dispense process has been completed. Such measurements can be useful in determining how quickly the system returns to the measured baseline value, for example where the filter is plugged and the pressure decreases more slowly to baseline. A step 414 generates a signal profile. The step generates a profile from the measured sensor data. For example the profile can include a peak or integral over time of the measured sensor data as described above. A step 416 determines a reference profile for comparison. The reference profile is determined so as to correspond with the liquid delivery plan, for example selecting reference profile having the same volume, dispense time and chemical composition as the delivery plan. As described above, the delivery plan can be determined by calculation, for example interpolation. A step 418 compares the reference profile to the measured profile. The comparison includes a less than or greater than comparison of integrals and peaks as described above, for example subtraction of the reference profile from the measured profile. The comparison can also include cross correlation, for example with time series measurement data and time series reference profiles. A step 420 generates a system status signal. The system status signal is generated in response to the comparison between the measurement profile and the reference profile. If the comparison shows little variation between the measurement profile and reference profile, the controller generates an OK signal. If the variation is sufficiently large, the controller generates a warning signal. If the variation is even larger, for example large enough to indicate system failure, the controller generates a failure signal.

It should be appreciated that the specific steps illustrated in FIG. 4 provide a particular method of monitoring a dispense of a semiconductor process liquid according to an embodiment of the present invention. Other sequences of steps may also be performed according to alternative embodiments. For example, alternative embodiments of the present invention may perform the steps outlined above in a different order. Moreover, the individual steps illustrated in FIG. 4 may include multiple sub-steps that may be performed in various sequences as appropriate to the individual step. Furthermore, additional steps may be added or removed depending on the particular applications. One of ordinary skill in the art would recognize many variations, modifications, and alternatives.

While the present invention has been described with respect to particular embodiments and specific examples thereof, it should be understood that other embodiments may fall within the spirit and scope of the invention. The scope of the invention should, therefore, be determined with reference to the appended claims along with their full scope of equivalents.

What is claimed is:

1. A method of monitoring a dispense of a semiconductor process liquid, the method comprising:
driving a motor to dispense the semiconductor process liquid in accordance with a liquid delivery plan, the delivery plan corresponding to a reference profile;
measuring a signal profile from a sensor while the motor dispenses the process liquid in accordance with the delivery plan; and
comparing the measured signal profile with the reference profile to characterize the dispense.

2. The method of claim 1 wherein the measured signal profile comprises an integral of a signal from the sensor while the motor dispense the liquid.

3. The method of claim 1 wherein the measured signal profile comprises a peak of a signal from the sensor while the motor dispense the liquid.

4. The method of claim 1 wherein the reference profile comprises a typical profile.

5. The method of claim 1 wherein the motor comprises a servo motor and the sensor comprises a current sensor, wherein the measured signal profile comprises a measured current profile and the reference profile comprises a reference current profile, and wherein the measured current profile is compared with the reference current profile to characterize the dispense.

6. A device for monitoring a dispense of a semiconductor process liquid, the device comprising:
an electrical motor to dispense a semiconductor process liquid in accordance with a liquid delivery plan;
a sensor to measure a profile of a dispense characteristic while the motor dispenses the liquid; and
a processor coupled to the sensor, the processor adapted to determine a reference profile to correspond with the delivery plan, the processor adapted to compare the measured profile with the reference profile to characterize the dispense.

7. The device of claim 6 wherein the processor comprises a tangible medium with at least one reference profile stored on tangible medium.

8. The device of claim 6 wherein the processor selects the reference profile from among several reference profiles to determine the reference profile, and wherein the reference profile is selected to correspond with the delivery plan.

9. The device of claim 6 wherein the sensor comprises at least one of a current sensor, a pressure sensor, a temperature sensor or an optical sensor.

10. The device of claim 6 wherein the motor comprises a servo motor and the sensor comprises a current sensor to measure an electrical current to the servo motor, and wherein the dispense characteristic comprises the electrical current to the motor.

11. The device of claim 10 wherein the reference profile comprises a reference current profile.

12. The device of claim 6 wherein the sensor comprises an optical sensor adapted to detect the liquid at a location on a semiconductor wafer and the measured profile comprises a time for the liquid to spread to the location.

13. The device of claim 6 wherein the sensor comprises a pressure sensor adapted to measure a pressure of the liquid while the motor dispenses the liquid and the measured profile comprises the pressure while motor dispenses the liquid.

14. The device of claim 6 wherein the sensor comprises a temperature sensor adapted to measure a temperature while the motor dispenses the liquid and the measured profile comprises the temperature while the motor dispenses the liquid.

15. A device for monitoring a dispense of a semiconductor process liquid, the device comprising:
an electrical motor to dispense the semiconductor process liquid;
a sensor to measure a characteristic profile of the liquid while the motor dispenses the liquid;
a processor connected to the sensor, the processor adapted to compare the measured characteristic profile to a reference profile.

16. The device of claim 15 wherein the sensor comprises a pressure sensor and the measure characteristic profile comprises a measured pressure profile, wherein the reference profile comprises a reference pressure profile, and wherein the processor is adapted to compare the measured pressure profile to the reference pressure profile.

17. The device of claim 16 wherein a volume of the liquid is delivered in accordance with a liquid delivery plan, and the processor is adapted to characterize the volume of the dispense in response to the pressure profile.

18. The device of claim 15 wherein the sensor comprises an optical sensor and the measured characteristic profile comprises a measured time for the liquid to spread to a location on a substrate, wherein the reference profile comprises a reference time for the liquid to spread to the location on the substrate, and wherein the processor is adapted to compare the measured liquid spread time to the reference spread time.

19. The device of claim 15 wherein the sensor comprises a temperature sensor adapted to measure a temperature of the liquid and the measured characteristic profile comprises a measured temperature profile, wherein the reference profile comprises a reference temperature profile, wherein the processor is connected to the temperature sensor, and wherein the processor is adapted to compare the measured temperature profile to the reference temperature profile to characterize the dispense.

20. A device for monitoring a dispense of a semiconductor process liquid, the device comprising:
an electrical servo motor to drive the pump and dispense a semiconductor process liquid, the motor driven with an electrical current;
a current sensor to measure a profile of the electrical current to the motor while the motor dispenses the liquid;
an optical sensor to measure a time for the liquid to spread to a position on a substrate;
a processor connected to the motor to deliver the liquid in accordance with a liquid delivery plan, the processor connected to the current sensor and the optical sensor; and
wherein the processor is adapted to compare the measured current profile and the measured time with a reference current profile and a reference time to characterize the dispense, and wherein the reference current profile and the reference time correspond to the liquid delivery plan.
